(19) United States
(12) Patent Application Publication
(10) Pub. No.: US 2026/0202886 A1
(43) Pub. Date: Jul. 16, 2026

(54) ELECTRONIC DEVICE AND ELECTRONIC EQUIPMENT

(71) Applicants: HON HAI PRECISION INDUSTRY CO., LTD., New Taipei (TW); HONGFUJIN PRECISION INDUSTRY (WUHAN) CO., LTD., Wuhan (CN)

(72) Inventors: YI-SHENG LIN, New Taipei (TW); XIAO-HUI XU, Wuhan (CN); JUN-HUA TAN, Wuhan (CN); CHIA-MING CHANG, New Taipei (TW)

(21) Appl. No.: 19/256,564

(22) Filed: Jul. 1, 2025

(30) Foreign Application Priority Data
Jan. 14, 2025 (CN) 202510058224.6

(51) Int. Cl. G06F 1/18; H05K 5/02

(52) U.S. Cl. CPC G06F 1/188; G06F 1/181; H05K 5/0221; H05K 5/023

(57) ABSTRACT

An electronic device and electronic equipment are provided. The electronic device includes a mounting bracket, an electronic component, and a handle. The mounting bracket has a mounting slot with a slot opening extending along a first direction, a guide groove, and a limiting slot. The guide groove communicates with the mounting slot along a second direction and has a first supporting surface and a second supporting surface that are opposite to and spaced apart from each other along the first direction. The electronic component has a positioning portion. The handle is rotatably connected to the electronic component and has a protruding portion cooperating with the guide groove. The handle has a locked state in which the protruding portion is limited on a side of the second supporting surface away from the slot opening. The positioning portion is located at an end of the limiting slot away from the slot opening.

### FIELD

The present application relates to field of electronic component assembly technology, and in particular to an electronic device and electronic equipment.

### BACKGROUND

Usually, an electronic device includes a mounting bracket and an electronic component. When assembling the electronic component into the mounting bracket, the electronic component is inserted vertically into the mounting bracket.

However, when installing the electronic component, the electronic component may drop rapidly to the bottom of the mounting bracket, causing damages.

Thus, there is room for improvement within the art.

### BRIEF DESCRIPTION OF THE DRAWINGS

Many aspects of the disclosure can be better understood with reference to the following drawings. The drawings in the following description are some embodiments of the present disclosure. For those of ordinary skill in the art, other drawings can be obtained based on these drawings without creative work.

FIG. 1 is a structural schematic view of an electronic equipment according to an embodiment of the present application.

FIG. 2 is a schematic view of an electronic device and a connector according to the embodiment shown in FIG. 1 in an assembly state.

FIG. 3 is a structural schematic view of the electronic device according to the embodiment shown in FIG. 1.

FIG. 4 is an exploded view of an electronic component and a mounting bracket according to the embodiment shown in FIG. 1.

FIG. 5 is a structural schematic view of the mounting bracket according to the embodiment shown in FIG. 1.

FIG. 6 is a schematic view of the electronic device according to the embodiment shown in FIG. 1 in a first assembly state.

FIG. 7 is a schematic view of the electronic device according to the embodiment shown in FIG. 1 in a second assembly state.

FIG. 8 is a partial structural schematic view of the electronic device according t the embodiment shown in FIG. 1.

### DETAILED DESCRIPTION

In order to make the above-mentioned objects, features and advantages of the present application more obvious, a detailed description of specific embodiments of the present application will be described in detail with reference to the accompanying drawings. A number of details are set forth in the following description so as to fully understand the present application. However, the present application can be implemented in many other ways different from those described herein, and those skilled in the art can make similar improvements without violating the contents of the present application. Therefore, the present application is not to be considered as limiting the scope of the embodiments described herein.

Several definitions that apply throughout this disclosure will now be presented.

The term “coupled” is defined as coupled, whether directly or indirectly through intervening components, and is not necessarily limited to physical connections. The connection may be such that the objects are permanently coupled or releasably coupled. The term “substantially” is defined to be essentially conforming to the particular dimension, shape, or other feature that the term modifies, such that the component need not have that exact feature. The term “comprising,” when utilized, means “including, but not necessarily limited to”; it in one embodiment indicates open-ended inclusion or membership in the so-described combination, group, series, and the like.

Unless otherwise defined, all technical and scientific terms used herein have the same meaning as commonly understood by one skilled in the art. The terms used in the specification of the present application herein are only for describing specific embodiments and are not intended to limit the present application. The terms “and/or” used herein includes any and all combinations of one or more of associated listed items.

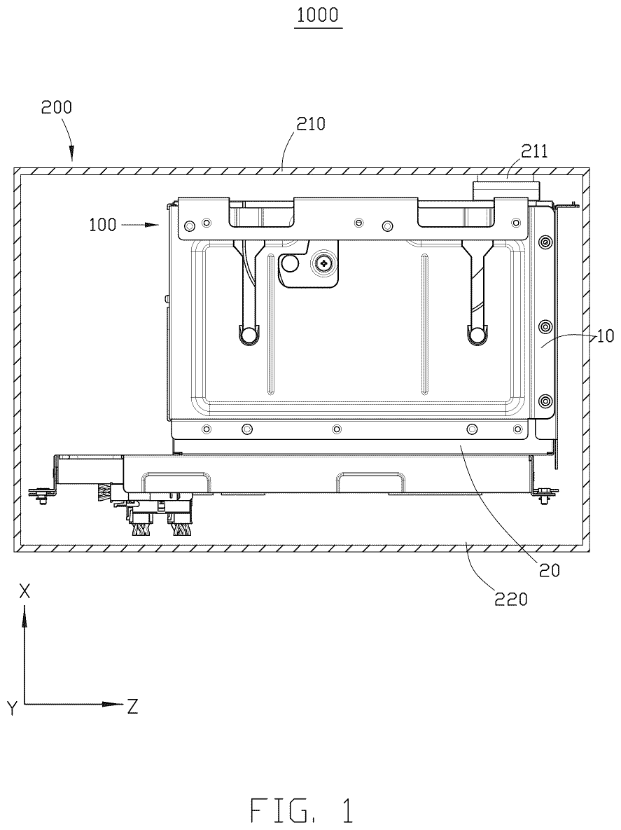

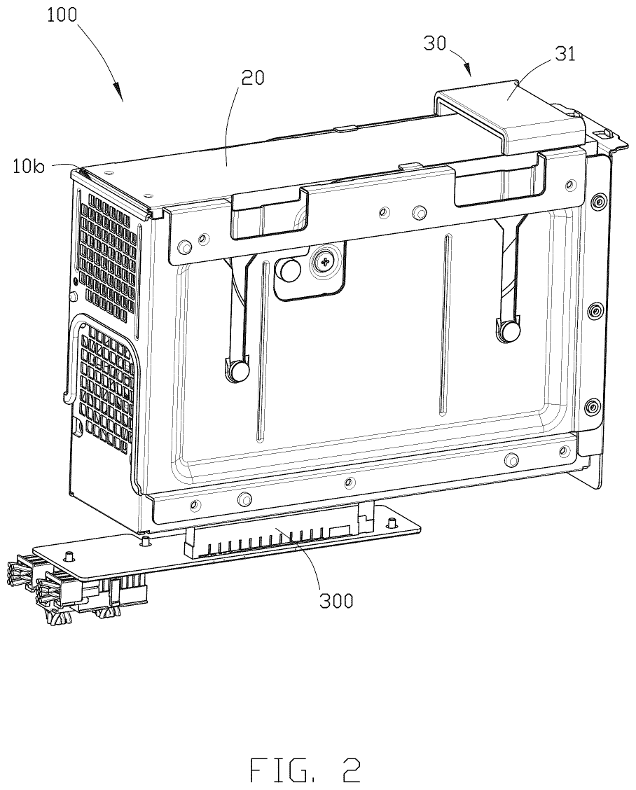

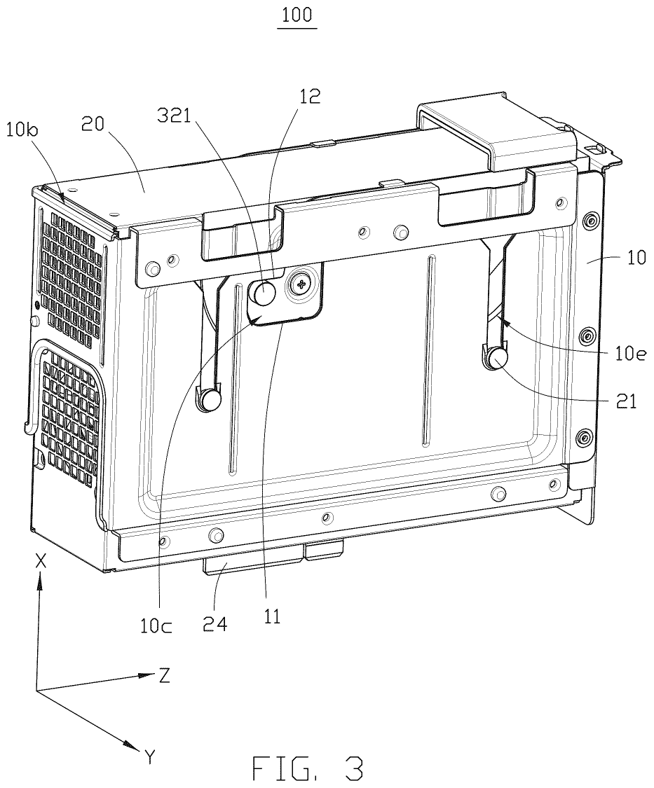

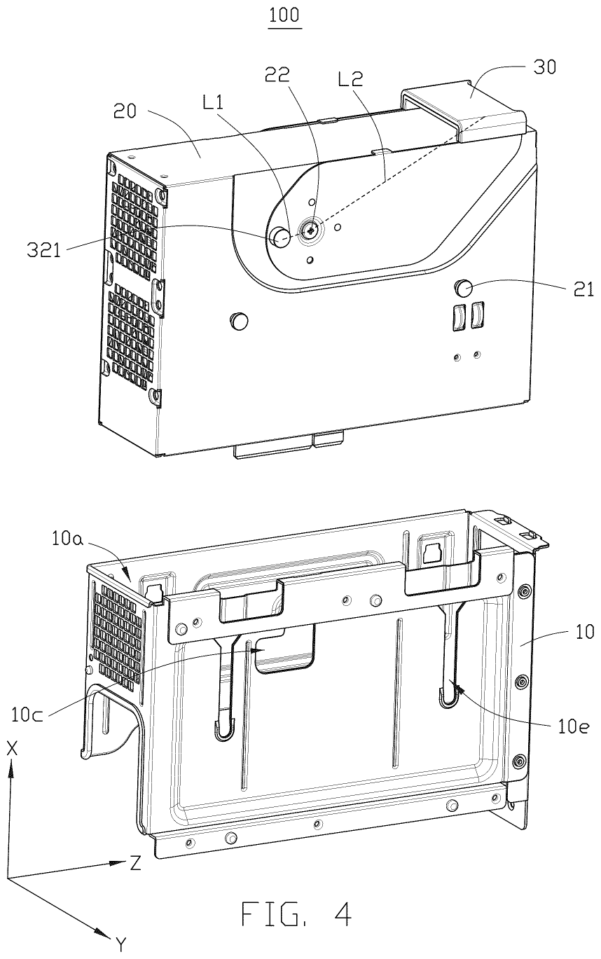

FIG. 1 is a structural schematic view of an electronic equipment 1000 according to an embodiment of the present application. FIG. 2 is a schematic view of an electronic device 100 and a connector 300 according to the embodiment shown in FIG. 1 in an assembly state. FIG. 3 is a structural schematic view of the electronic device 100 according to the embodiment shown in FIG. 1. FIG. 4 is an exploded view of an electronic component 20 and a mounting bracket 10 according to the embodiment shown in FIG. 1.

Referring to FIG. 1, in one embodiment, an electronic equipment 1000 is provided, which may be a workstation or other type of computer. The electronic equipment 1000 includes a chassis 200 and an electronic device 100. Referring to FIG. 2 to FIG. 4, the electronic device 100 includes a mounting bracket 10. The mounting bracket 10 has a mounting slot 10a, the mounting slot 10a is configured to mount an electronic component 20, and the mounting slot 10a has a slot opening 10b extending along a first direction X. The mounting bracket 10 is mounted inside the chassis 200.

Therefore, when the electronic component 20 needs to be assembled inside the chassis 200, the mounting bracket 10 is first fixed inside the chassis 200, and then the electronic component 20 is inserted into the mounting slot 10a to complete the assembly of the electronic component 20.

In one embodiment, the electronic component 20 is a power supply unit (PSU), used to supply power to other components of the computer. In other embodiments, the electronic component 20 may be other devices that need to be assembled in the chassis 200.

In some embodiments, as shown in FIG. 2, the electronic equipment 1000 further includes a connector 300, the connector 300 is provided inside the chassis 200 (shown in FIG. 1) and located outside an end of the mounting bracket 10 away from the slot opening 10b. Referring to FIG. 3, an end of the electronic component 20 away from the slot opening 10b extends beyond the mounting bracket 10 and has a connecting portion 24. The electronic component 20 has a locked state. In the locked state, the connecting portion 24 is inserted into the connector 300 to form an electrical connection between the electronic component 20 and the connector 300.

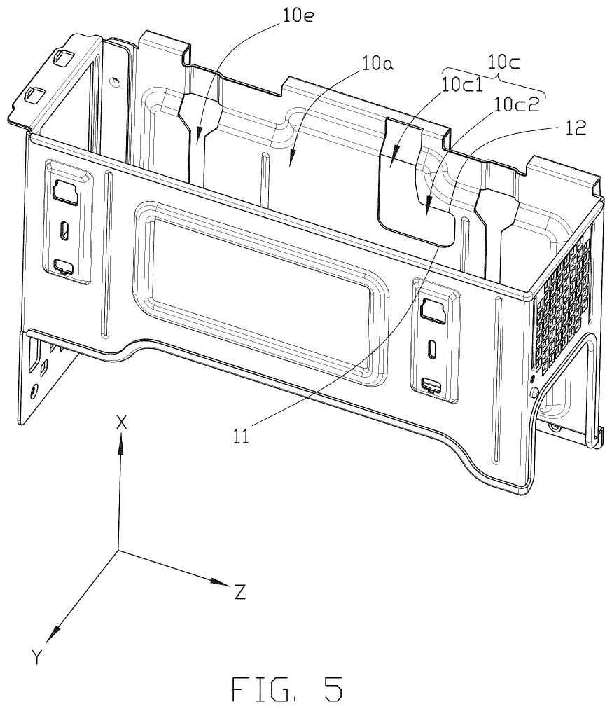

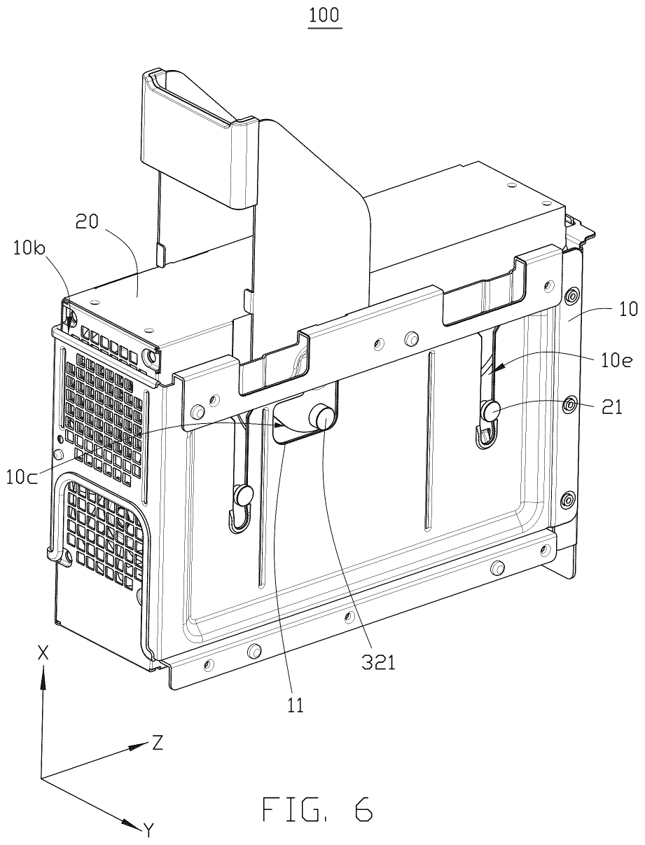

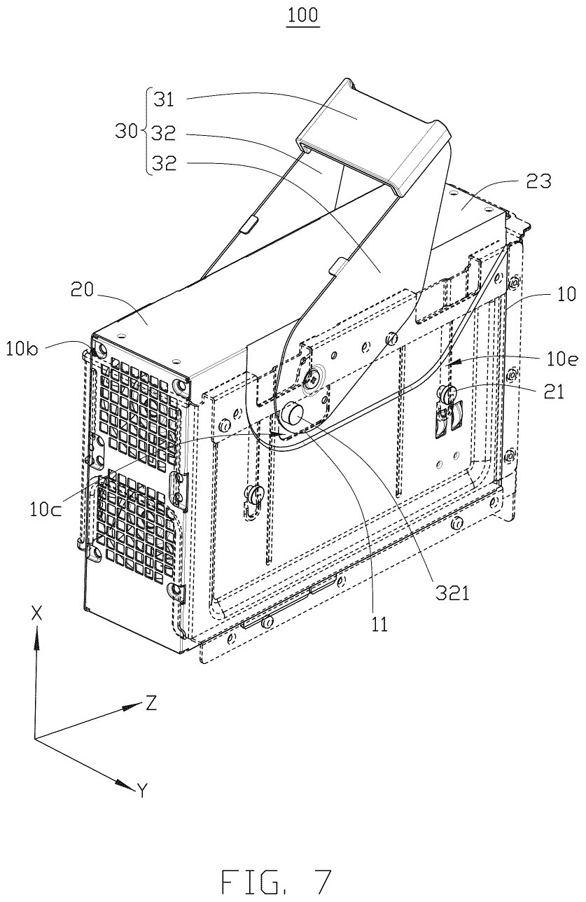

FIG. 5 is a structural schematic view of the mounting bracket 10 according to the embodiment shown in FIG. 1. FIG. 6 is schematic view of the electronic device 100 according to the embodiment shown in FIG. 1 in a first assembly state. FIG. 7 is schematic view of the electronic device 100 according to the embodiment shown in FIG. 1 a second assembly state.

Referring to FIG. 3 to FIG. 5, the electronic device 100 of one embodiment further includes a handle 30. The mounting bracket 10 further has a guide groove 10c and one or more limiting slots 10e. The guide groove 10c communicates with one side of the mounting slot 10a along a second direction Y. The guide groove 10c has a first supporting surface 11 and a second supporting surface 12 that are opposite to and spaced apart from each other along the first direction X. The second supporting surface 12 is located between the first supporting surface 11 and the slot opening 10b. The limiting slot 10e extends along the first direction X. The second direction Y is perpendicular to the first direction X. The electronic component 20 is mounted in the mounting slot 10a. A positioning portion 21 is provided at one side of the electronic component 20 along the second direction Y. The limiting slot 10e limits movement of the positioning portion 21 along the first direction X. The handle 30 is rotatably connected to the electronic component 20, and the handle has a protruding portion 321 cooperating with the guide groove 10c. The handle 30 has a locked state. As shown in FIG. 3, in the locked state, the protruding portion 321 is limited on a side of the second supporting surface 12 away from the slot opening 10b, and the positioning portion 21 is located at an end of the limiting slot 10e away from the slot opening 10b. As shown in FIG. 6 and FIG. 7, the first supporting surface 11 and the second supporting surface 12 are respectively configured to support the protruding portion 321 during the process of inserting the electronic component 20 into the mounting slot 10a along the first direction X. In one embodiment, the protruding portion 321 passes through the guide groove 10c in the second direction Y. The positioning portion 21 passes through the limiting slot 10e in the second direction Y. Therefore, the protruding portion 321 and the positioning portion 21 are not slip easily from the guide groove 10c and the limiting slot 10e.

In the electronic device 100, when installing the electronic component 20, the electronic component 20 is inserted into the mounting slot 10a through the slot opening 10b along the first direction X. The mounting bracket 10 further has a guide groove 10c communicating with the mounting slot 10a. The guide groove 10c has a first supporting surface 11 and a second supporting surface 12 opposite to each other along the first direction X, and the second supporting surface 12 located between the slot opening 10b and the first supporting surface 11. When inserting the electronic component 20 into the mounting slot 10a along the first direction X, the protruding portion 321 can abut against the first supporting surface 11, preventing the electronic component 20 from rapidly dropping to the bottom of the mounting bracket 10 along the first direction X. At this time, the handle 30 can be operated to rotate relative to the electronic component 20, making the protruding portion 321 rotate from abutting against the first supporting surface 11 to abutting against the second supporting surface 12. Then rotate the handle 30 to make the protruding portion 321 rotate relative to the second supporting surface 12 until the positioning portion 21 drops into the end of the limiting slot 10e away from the slot opening 10b along the first direction X, thereby reaching the locked state of the handle 30. Since the protruding portion 321 is respectively supported by the first supporting surface 11 and the second supporting surface 12 during the process of inserting the electronic component 20 into the mounting slot 10a to reaching the locked state, it prevents the electronic component 20 from rapidly falling and colliding with the bottom of the mounting bracket 10, thus reducing the risk of damage during installation of the electronic component 20. Moreover, since the positioning portion 21 is movably fitted in the limiting slot 10e along the first direction X, it provides guidance for the movement of the electronic component 20 along the first direction X, making the assembly process more stable, and in the locked state, the positioning portion 21 is located at the end of the limiting slot 10e away from the slot opening 10b, ensuring precise positioning in the locked state.

During assembly process, the first direction X can be the gravity direction to facilitate the insertion and removal of the electronic component 20. The electronic device 100 prevents the electronic component 20 from rapidly falling and colliding under its own gravity.

During assembly process, after the protruding portion 321 rotates from the first supporting surface 11 to contact the second supporting surface 12, rotate the handle 30 to make it pivot around the protruding portion 321, causing the electronic component 20 to move downward along the first direction X under lever action, and the connecting portion 24 begins to mate with the connector 300, until the positioning portion 21 engages with the end of the limiting slot 10e away from the slot opening 10b, at which point the connecting portion 24 is properly assembled with the connector 300. When disassembling the electronic component 20, first rotate the handle 30 to make the protruding portion 321 rotate from the second supporting surface 12 to contact the first supporting surface 11, then continue rotating the handle 30 to make it pivot around the protruding portion 321, causing the electronic component 20 to lift upward under lever action. When the handle 30 rotates to vertical position, the connecting portion 24 completely disengages from the connector 300, and lifting the electronic component 20 upward completes the disassembly. Optionally, the protruding portion 321 is constructed to be cylindrical. Axis of the protruding portion 321 is parallel to the second direction Y.

In some embodiments, as shown in FIG. 5 to FIG. 7, the guide groove 10c includes a first guide groove 10c1 and a second guide groove 10c2. The first guide groove 10c1 extends along the first direction X, and the second guide groove 10c2 extends along a third direction Z. One end of the second guide groove 10c2 along the third direction Z communicates with an end of the first guide groove 10c1 away from the slot opening 10b. The third direction Z is perpendicular to both the first direction X and the second direction Y. The second guide groove 10c2 is defined between the first supporting surface 11 and the second supporting surface 12. One end of the first supporting surface 11 along the third direction Z extends beyond the second supporting surface 12 and defines a groove bottom surface at the end of the first guide groove 10c1 away from the slot opening 10b. Therefore, during the installation of the electronic component 20, one can first hold the handle 30 to make the electronic component 20 descend along the first direction X, allowing the protruding portion 321 to move along the first direction X within the first guide groove 10c1 until the protruding portion 321 abuts against the first supporting surface 11, then rotate the handle 30 to make the protruding portion 321 rotate from the first guide groove 10c1 into the second guide groove 10c2 and abut against the second supporting surface 12.

In some embodiments, as shown in FIG. 4, there are multiple positioning portions 21 spaced apart along the third direction Z. There are multiple limiting slots 10e one-to-one corresponding to the positioning portions 21. When the handle 30 is in the locked state, a groove bottom surface of a corresponding limiting slot 10e of the multiple limiting slots 10e abuts against each of the positing portions 21 at an end of the corresponding limiting slots 10e away from the slot opening 10b of the mounting slot 10a. Therefore, by providing multiple positioning portions 21 and multiple limiting slots 10e, the stability of the electronic component 20 during assembly is further improved.

In some embodiments, as shown in FIG. 4, the guide groove 10c is oriented so that the second direction Y is parallel to an axis of a pivot shaft 22 of electronic component 20. The handle 30 is rotatably connected to the pivot shaft 22, and the protruding portion 321 of the handle 30 is arranged spaced apart from the pivot shaft 22. This allows the handle 30 to provide supporting force to the electronic component 20 through the pivot shaft 22.

In some embodiments, as shown in FIG. 7, the electronic component 20 has a top surface 23 on a side close to the slot opening 10b along the first direction X. The handle 30 includes an operating portion 31 and two rotating arms 32. The two rotating arms 32 are respectively located on two sides of the electronic component 20 along the second direction Y. The rotating arms 32 are rotatably connected to the pivot shaft 22 (shown in FIG. 4). The operating portion 31 connects between ends of the two rotating arms 32 that extend beyond the top surface 23. The protruding portion 321 is provided at an end of the rotating arm 32 away from the operating portion 31, and the pivot shaft 22 is located between the protruding portion 321 and the operating portion 31. This allows operation of the handle 30 to rotate relative to the electronic component 20 or drive the electronic component 20 to move through the operating portion 31, making assembly or disassembly operations more convenient. For example, during assembly, one can first hold the operating portion 31 to keep the handle 30 vertical and make the electronic component 20 descend until the protruding portion 321 abuts against the first supporting surface 11, then press the operating portion 31 towards the top surface 23 to make the protruding portion 321 abut against the second supporting surface 12, and continue pressing the operating portion 31 towards the top surface 23 to make the electronic component 20 descend to the locked state under lever action. During disassembly, first pull the operating portion 31 away from the top surface 23 to rotate the handle 30 relative to the electronic component 20 until the protruding portion 321 contacts the first supporting surface 11, then pull the operating portion 31 upward to make the electronic component 20 rise under lever action until the handle 30 rotates to vertical position, then lift the operating portion 31 upward to remove the electronic component 20 from the mounting bracket 10.

In some embodiments, as shown in FIG. 4, when assembling the electronic component 20 into the electronic device 100, on a plane perpendicular to the second direction Y, a distance L1 between the pivot shaft 22 and the protruding portion 321 is smaller than a distance L2 between the pivot shaft 22 and the operating portion 31. This makes the operation more effortless when the electronic component 20 descends or rises under lever action.

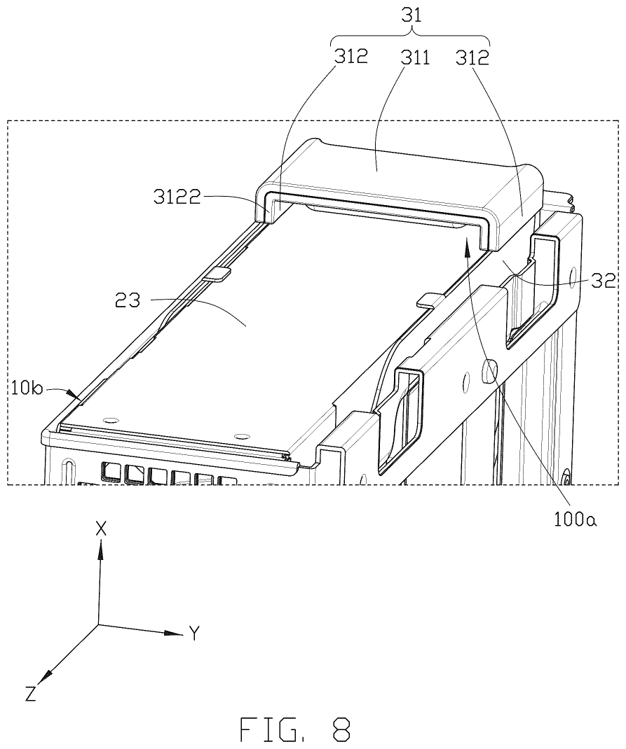

FIG. 8 is a partial structural schematic view of the electronic device 100 according to the embodiment shown in FIG. 1.

In some embodiments, as shown in FIG. 8, the operating portion 31 includes a gripping portion 311 and two bent portions 312. The two bent portions 312 are respectively connected to two sides of the gripping portion 311 along the second direction Y, and the two bent portions 312 are respectively connected to the ends of the two rotating arms 32 that extend beyond the top surface 23. Each bent portion 312 has a limiting portion 3121 on a side close to the other bent portion 312 along the second direction Y. In the locked state, the limiting portions 3121 abut against the top surface 23 along the first direction X, a gap 100a is formed between the gripping portion 311 and the top surface 23, facilitating insertion of fingers into the gap 100a to pull the handle 30 during operation.

In some embodiments, as shown in FIG. 1, the mounting bracket 10 is configured to be mounted to a chassis 200. The chassis 200 includes a side cover 210 and a housing 220. The housing 220 is configured to mount the mounting bracket 10. The side cover 210 is detachably provided on one side of the housing 220 along the first direction X, and the side cover 210 is corresponded to the slot opening 10b (shown in FIG. 2). The side cover 210 has an elastic structure 211 (such as a rubber block) on a side facing the slot opening 10b. The elastic structure 211 is configured to abut against the operating portion 31 along the first direction X. Therefore, the side cover 210 applies pressure to the handle 30 through the elastic structure 211 in a direction away from the side cover 210, preventing rotation of the handle 30 to ensure the electronic component 20 remains in the locked state, improving reliability during transportation and use. For example, when the chassis 200 falls towards the side cover 210, the handle 30 receives pressure from the elastic structure 211 in a direction away from the side cover 210, and the protruding portion 321 receives a force from the first supporting surface 11 in a direction away from the side cover 210, keeping the handle 30 locked in the locked state and preventing it from disengaging.

The above electronic device 100 prevents damage from dropping during assembly of the electronic component 20, improves yield rate, enhances stability during assembly, and ensures precise positioning in the locked state. The structure of the electronic device 100 is simple, reduces manufacturing costs, and is conducive to improving production and quality stability.

It should be noted that in FIG. 7, some lines are shown as dashed lines to provide visibility of internal structures.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. An electronic device comprising:
a mounting bracket comprising a mounting slot, the mounting slot comprising a slot opening extending along a first direction, the mounting bracket further comprising a guide groove and one or more limiting slots, the guide groove communicating with one side of the mounting slot along a second direction and comprising a first supporting surface and a second supporting surface, wherein:
the first supporting surface is opposite to and spaced apart from the second supporting surface along the first direction,
the second supporting surface is located between the first supporting surface and the slot opening,
the one or more limiting slots extend along the first direction,
the second direction is perpendicular to the first direction,
the mounting slot is configured to mount an electronic component and at least one positioning portion on one side of the electronic component, and
the one or more limiting slots limit movements of the positioning portion along the first direction; and
a handle configured to rotatably connect to an electronic component, the handle comprising a protruding portion cooperating with the guide groove, wherein when the handle is in a locked state, the protruding portion is limited on a side of the second supporting surface away from the slot opening, and an end of the limiting slot away from the slot opening abuts a positioning portion of the electronic component, wherein
the first supporting surface and the second supporting surface support the protruding portion when the mounting slot receives the electronic component along the first direction.

2. The electronic device according to claim 1, wherein the guide groove further comprises a first guide groove and a second guide groove;
the first guide groove extends along the first direction, the second guide groove extends along a third direction, one end of the second guide groove along the third direction communicates with an end of the first guide groove away from the slot opening; the third direction is perpendicular to each of the first direction and the second direction;
the second guide groove is between the first supporting surface and the second supporting surface, one end of the first supporting surface along the third direction extends beyond the second supporting surface and defines a groove bottom surface at the end of the first guide groove away from the slot opening.

3. The electronic device according to claim 1, wherein:
the mounting bracket comprises multiple limiting slots one-to-one corresponding to the at least one positioning portion of the electronic component, when the handle is in the locked state, a groove bottom surface of a corresponding limiting slot of the multiple limiting slots abuts against each of the at least one position portion at an end of the corresponding limiting slot away from the slot opening of the mounting slot.

4. The electronic device according to claim 1, wherein the guiding groove is oriented so that the second direction is parallel to an axis of a pivot shaft of the electronic component;
the handle is further configured to rotatably connect to the pivot shaft of the electronic component;
the protruding portion of the handle is arranged spaced apart from the pivot shaft.

5. The electronic device according to claim 4, wherein the handle further comprises an operating portion and two rotating arms, the protruding portion is provided at ends of the two rotating arms away from the operating portion;
when assembling the electronic component into the electronic device, the two rotating arms are respectively positioned on two sides of the electronic component along the second direction and ends of the two rotating arms extend beyond a top surface of the electronic component, the top surface of the electronic component is close to the slot opening along the first direction, the rotating arms rotatably connect to the pivot shaft, the operating portion connects between the ends of the two rotating arms, the pivot shaft is between the protruding portion and the operating portion.

6. The electronic device according to claim 5, wherein on a plane perpendicular to the second direction, when assembling the electronic component into the electronic device, a distance between the protruding portion and the pivot shaft is smaller than a distance between the operating portion and the pivot shaft.

7. The electronic device according to claim 5, wherein the operating portion comprises a gripping portion and two bent portions;
the two bent portions are respectively connected to two sides of the gripping portion along the second direction, the two bent portions are further respectively connected to the ends of the two rotating arms;
each of the two bent portion comprises a limiting portion on a side close to another bent portion of the two bend portion along the second direction, when the handle is in the locked state, the limiting portion abuts against the top surface of the electronic component along the first direction, and a gap is formed between the gripping portion and the top surface.

8. The electronic device according to claim 5, further comprising a chassis comprising a side cover and a housing, wherein,
the housing is configured to mount the mounting bracket;
the side cover is detachably provided on one side of the housing along the first direction; and
the side cover comprises an elastic structure on a side facing the slot opening, the elastic structure is configured to abut against the operating portion along the first direction.

9. The electronic device according to claim 1, wherein, the protruding portion passes through the guide groove along the second direction.

10. The electronic device according to claim 1, wherein, when inserting the electronic component into the mounting slot along the first direction, and the handle is not in the locked state, the protruding portion of the handle abuts against the first supporting surface.

11. An electronic equipment, comprising:
a chassis; and
an electronic device, comprises:
a mounting bracket mounted inside the chassis, the mounting bracket comprising a mounting slot, the mounting slot comprising a slot opening extending along a first direction, the mounting bracket further comprising a guide groove and one or more limiting slot, the guide groove communicating with one side of the mounting slot along a second direction and comprising a first supporting surface and a second supporting surface, wherein:
the first supporting surface is opposite to and spaced apart from the second supporting surface along the first direction,
the second supporting surface is located between the first supporting surface and the slot opening,
the one or more limiting slots extend along the first direction,
the second direction is perpendicular to the first direction,
the mounting slot is configured to mount an electronic component and at least one positioning portion is on one side of the electronic component, and
the one ore more limiting slots limit movements of the positioning portion along the first direction; and
a handle configured to rotatably connect to the electronic component, the handle has a protruding portion cooperating with the guide groove, wherein when the handle is in a locked state, the protruding portion is limited on a side of the second supporting surface away from the slot opening, and an end of the limiting slot away form the slot opening abuts a positioning portion of the electronic component, wherein
the first supporting surface and the second supporting surface support the protruding portion when the mounting slot receives the electronic component along the first direction.

12. The electronic equipment according to claim 11, further comprising a connector provided inside the chassis and located outside an end of the mounting bracket away from the slot opening, wherein,
when the handle is in the locked state, the connector is configured to couple with a connecting portion at an end of the electronic component away from the slot opening and extending beyond the mounting bracket.

13. The electronic equipment according to claim 11, wherein the guide groove further comprises a first guide groove and a second guide groove;
the first guide groove extends along the first direction, the second guide groove extends along a third direction, one end of the second guide groove along the third direction communicates with an end of the first guide groove away from the slot opening; the third direction is perpendicular to both the first direction and the second direction;
the second guide groove is between the first supporting surface and the second supporting surface, one end of the first supporting surface along the third direction extends beyond the second supporting surface and defines a groove bottom surface at the end of the first guide groove away from the slot opening.

14. The electronic equipment according to claim 11, wherein the mounting bracket comprises multiple limiting slots one-to-one corresponding to the at least one positioning portion of the electronic component, when the handle is in the locked state, a groove bottom surface of a corresponding limiting slot of the multiple limiting slots abuts against each of the at least one positing portion at an end of the corresponding limiting slot away from the slot opening of the mounting slot.

15. The electronic equipment according to claim 11, wherein the guiding groove is oriented so that the second direction is parallel to an axis of a pivot shaft of the electronic component;
the handle is further configured to rotatably connect to the pivot shaft of the electronic component;
the protruding portion of the handle is arranged spaced apart from the pivot shaft.

16. The electronic equipment according to claim 15, wherein the handle further comprises an operating portion and two rotating arms, the protruding portion is provided at an end of the rotating arm away from the operating portion,
when assembling the electronic component into the electronic device, the two rotating arms are respectively positioned on two sides of the electronic component along the second direction and ends of the two rotating arms extend beyond a top surface of the electronic component, the top surface of the electronic component is close to the slot opening along the first direction, the rotating arms are rotatably connected to the pivot shaft, the operating portion connects between the ends of the two rotating arms; the pivot shaft is between the protruding portion and the operating portion.

17. The electronic equipment according to claim 16, wherein on a plane perpendicular to the second direction, when assembling the electronic component into the electronic device, a distance between the pivot shaft and the protruding portion is smaller than a distance between the pivot shaft and the operating portion.

18. The electronic equipment according to claim 16, wherein the operating portion comprises a gripping portion and two bent portions;
the two bent portions are respectively connected to two sides of the gripping portion along the second direction, the two bent portions are further respectively connected to the ends of the two rotating arms;
each of the two bent portion comprises a limiting portion on a side close to another bent portion of the two bend portion along the second direction, when the handle is in the locked state, the limiting portion abuts against the top surface of the electronic component along the first direction, and a gap is formed between the gripping portion and the top surface.

19. The electronic equipment according to claim 16, wherein the chassis comprises a side cover and a housing, wherein,
the housing is configured to mount the mounting bracket;
the side cover is detachably provided on one side of the housing along the first direction; and
the side cover comprises an elastic structure on a side facing the slot opening, the elastic structure is configured to abut against the operating portion along the first direction.

20. The electronic equipment according to claim 11, wherein, when inserting the electronic component into the mounting slot along the first direction, and the handle is not in the locked state, the protruding portion of the handle abuts against the first supporting surface.
